(19) United States
(12) Patent Application Publication
(10) Pub. No.: US 2008/0002384 A1
(43) Pub. Date: Jan. 3, 2008

(54) APPARATUS FOR PROVIDING RADIO FREQUENCY SHIELDING AND HEAT DISSIPATION FOR ELECTRONIC COMPONENTS

(75) Inventor: John D. Fiske, Margate, FL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(73) Assignee: MOTOROLA, INC., Plantation, FL (US)

(21) Appl. No.: 11/427,903

(22) Filed: Jun. 30, 2006

(51) Int. Cl. H05K 9/00

(52) U.S. Cl. 361/818

(57) ABSTRACT

An apparatus (200) and method to provide radio frequency (RF) shielding and heat dissipation to electronic components (104, 106 and 108) mounted on a printed circuit board (PCB) (110) are provided. The apparatus includes an RF shield (202) enclosing the electronic components mounted on the PCB. The apparatus also includes an adhesive pad (204) which is thermally conductive and is in physical contact with at least one electronic component. The RF shield has an inside surface and an outside surface. When a force (302) is applied on the outside surface, the RF shield bends and the inside surface sticks to the adhesive pad. Apparatus (200) provides both RF shielding and heat dissipation for electronic components.

### FIELD OF THE INVENTION

The present invention relates, in general, to a electronic circuits, and more particularly, to providing radio frequency shielding and heat dissipation for electronic components mounted on printed circuit boards.

### BACKGROUND OF THE INVENTION

Printed circuit boards (PCBs) are widely used in the electronics and telecommunications industry for connecting various components to a system. PCBs are generally made of an insulating substrate, e.g., plastic, on which an electrical circuit is formed by depositing a predetermined and well defined pattern of a conducting metal, e.g., copper.

The conducting metal connects various electronic components, e.g., filters, semiconductors, which are mounted on the PCB. Many of these electrical circuits, mounted on the PCBs, include electronic components that operate at high radio frequencies. The radio frequency (RF) emissions from these components can interfere with the proper operation of the other components or circuits on the PCB or in the vicinity of the PCB, e.g., on other PCBs. Therefore, it is important to block or shield these RF emissions in order to prevent RF interference. To counter this problem, an RF shield is typically used to enclose the components on the PCBs and block the RF emissions. However, in conjunction with shielding the components, heat radiated from, for example high power devices, may not be dissipated properly. This heat reduces the efficiency of the circuit, changes the characteristics of electronic components and can even damage the electronic components.

In light of the foregoing discussion, it would be highly desirable to have an improved RF shielding apparatus that can enhance the cooling of electronic components in conjunction with blocking RF emissions.

### BRIEF DESCRIPTION OF THE DRAWINGS

The accompanying figures, where like reference numerals refer to identical or functionally similar elements throughout the separate views, and which, together with the detailed description below, are incorporated in and form part of the specification, serve to further illustrate various embodiments and to explain various principles and advantages, all in accordance with the present invention.

The present invention is illustrated by way of example, and not limitation, in the accompanying figures, in which like references indicate similar elements, and in which:

FIG. 1 is an exemplary side view of an RF shield enclosing a plurality of electronic components mounted on a printed circuit board as known in the art;

FIG. 2 depicts an RF shield enclosing a plurality of electronic components mounted on a printed circuit board, in accordance with various embodiments of the present invention;

FIG. 3 depicts an exemplary compressed structure of the RF shield, in accordance with an embodiment of the present invention; and

FIG. 4 is a flow chart illustrating a method for providing RF shielding to the plurality of electronic components mounted on the PCB

Skilled artisans will appreciate that elements in the figures are illustrated for simplicity and clarity and have not necessarily been drawn to scale. For example, the dimensions of some of the elements in the figures may be exaggerated relative to other elements to help in improving an understanding of embodiments of the present invention.

### DETAILED DESCRIPTION OF THE DRAWINGS

Before describing in detail the particular apparatus and method for providing radio frequency shielding to electronic components, in accordance with various embodiments of the present invention, it should be observed that the present invention resides primarily in combinations of the apparatuses and components for providing radio frequency shielding. Accordingly, the apparatuses and components have been represented where appropriate by conventional symbols in the drawings, showing only those specific details that are pertinent for understanding the present invention, so as not to obscure the disclosure with details that will be readily apparent to those with ordinary skill in the art, having the benefit of the description herein.

In this document, relational terms such as first and second, and the like, may be used solely to distinguish one entity or action, from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such a process, method, article, or apparatus. An element proceeded by “comprises . . . a” does not, without more constraints, preclude the existence of additional identical elements in the process, method, article, or apparatus that comprises the element.

The term “another,” as used in this document, is defined as at least a second or more. The term “includes” as used herein, is defined as comprising.

In an embodiment, an apparatus for providing RF shielding to various electronic components mounted on a PCB is provided. The apparatus includes an adhesive pad which is thermally conductive and is in physical contact with various electronic components mounted on the PCB. The apparatus also includes an RF shield, which encloses the various electronic components and is capable of bending on application of force. The RF shield has an outside surface and an inside surface. When a force is applied on the outside surface of the RF shield, the shield bends and the inside surface makes physical contact with the adhesive pad.

In another embodiment, an apparatus for providing RF shielding to various electronic components in an electronic circuit is provided. The apparatus includes a base board on which various electronic components are mounted. The apparatus also includes an adhesive pad which is thermally conductive and is in physical contact with various electronic components mounted on the base board. Further, the apparatus includes an RF shield, which encloses the various electronic components and is capable of bending on application of force. The RF shield has a first surface and a second surface. When force is applied on the first surface of the RF shield, it bends and the second surface makes physical contact with the adhesive pad.

In yet another embodiment, a method for providing RF shielding to various electronic components mounted on a PCB is elaborated. The method includes placing an adhesive pad on the various electronic components. The adhesive pad is in physical contact with various electronic components. The method also includes forming an RF shield with a compressible top surface. Further, the method includes compressing the RF shield by application of force. In response to the applied force, the RF shield makes physical contact with the adhesive pad.

FIG. 1 is an exemplary side view of an RF shield 102 enclosing a plurality of electronic components 104, 106 and 108 mounted on a PCB 110 as known in the art. Examples of the plurality of electronic components 104, 106 and 108 include diodes, transistors, filters and the like. The electronic components 104, 106 and 108 radiate RF energy 112. Similarly, other components in the system or on PCB 110 radiate RF energy 114. The PCB 110 is made of an insulating substrate. Examples of the insulating substrate include plastic, paper impregnated with phenolic resin and the like. The plurality of the electronic components 104, 106 and 108 are mounted and connected electrically by depositing a predetermined pattern of conducting metal on the PCB 110. Examples of the conducting metal can be copper, aluminum and the like. The plurality of electronic components 104, 106 and 108 mounted on the PCB 110 are enclosed in the RF shield 102. The RF shield 102 may be made of metal or any other conducting material. During the operation of the plurality of electronic components 104, 106 and 108 at high frequencies, they radiate RF energy 112. The RF shield 102 blocks the RF energy 112 from radiating outside the RF shield 102 and prevents the radio frequency energy 114 from permeating the RF shield 102.

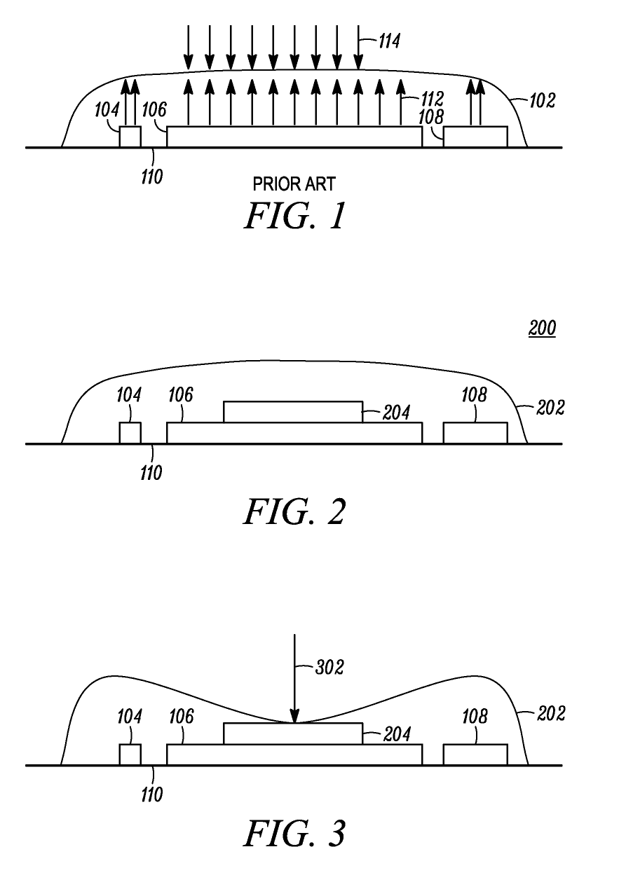

FIG. 2 depicts an apparatus 200 comprising an RF shield 202 enclosing the plurality of electronic components 104, 106 and 108 mounted on the PCB 110, in accordance with various embodiments of the present invention. In addition, the PCB 110 includes an adhesive pad 204. The plurality of electronic components 104, 106 and 108 being mounted and connected on the PCB 110 have been described in conjunction with FIG. 1. The adhesive pad 204 is thermally conductive and has adhesion properties that allow the pad 204 to stick to a metallic and/or a non metallic surface. The adhesive pad 204 of apparatus 200 is in physical contact with, and absorbs heat from, at least some of the plurality of electronic components 104, 106 and 108. For an embodiment of the present invention, the adhesive pad 204 can be in physical contact with the plurality of electronic components 104, 106 and 108. The adhesive pad 204 is enclosed by the RF shield 202 along with the plurality of electronic components 104, 106 and 108 placed on the PCB 110. The RF shield 202 may be made of metal or any other conducting material, and is compressible on the application of force. The RF shield 202 includes a top surface and side walls. These side walls are coupled with the PCB 110 to form an enclosure for the plurality of electronic components 104, 106 and 108 mounted on the PCB 110. The top surface includes an inside surface and an outside surface. The inside surface of the RF shield 202 is the surface facing the plurality of electronic components 104, 106 and 108, whereas the outside surface is on the other side of the enclosure on which a compressive force may be applied.

FIG. 3 depicts an exemplary compressed structure of the RF shield 202, in accordance with an embodiment of the present invention. FIG. 3 shows the PCB 110, the plurality of electronic components 104, 106 and 108, the adhesive pad 204 and the RF shield 202. The RF shield 202, with an outside surface and an inside surface, encloses the plurality of electronic components 104, 106, and 108, along with the adhesive pad 204. In order to compress the RF shield 202, a force 302 is applied on the outside surface of the RF shield 202. For an embodiment of the present invention, the force 302 can be applied vertically on the RF shield 202. The force 302 may be applied manually or automatically. For another embodiment of the present invention the force 302 is applied by an individual. On application of the force 302, the RF shield 202 adheres to the adhesive pad 204 which is in physical contact with the plurality of electronic components 104, 106 and 108. Therefore, the inside surface of the RF shield 202 has direct physical contact with the adhesive pad 204. The force 302 is applied to compress the RF shield 202 so that the heat radiated from the plurality of electronic components 104, 106 and 108 is easily dissipated through the physical connection among the electronic components 104, 106 and 108, adhesive pad 204 and the RF shield 202. For an embodiment of the present invention, the RF shield 202 is permanently attached to the adhesive pad 204.

For another embodiment of the present invention, the plurality of electronic components 104, 106 and 108 are mounted on a base board. The base board may be a PCB and can be made from an insulating material. The RF shield 202, which encloses the plurality of electronic components 104, 106 and 108, has a first surface and a second surface. The force 302 is applied on the first surface of the RF shield 202. On application of force 302, the RF shield 202 is compressed and the second surface of the RF shield comes into physical contact with the adhesive pad 204.

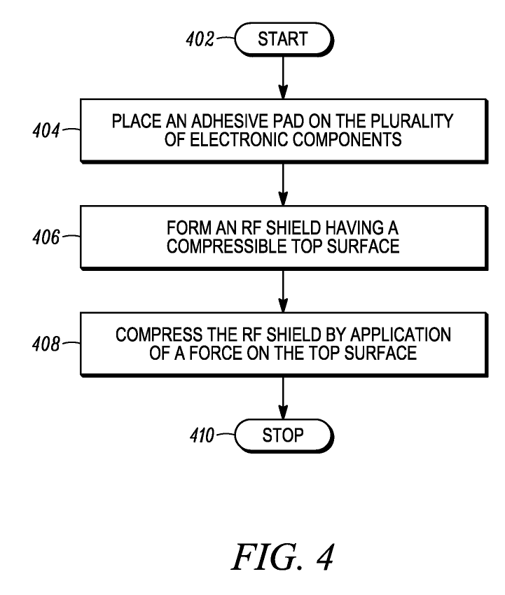

FIG. 4 is a flow chart illustrating a method for providing RF shielding to the plurality of electronic components 104, 106 and 108 mounted on the PCB 110. The method is initiated at step 402. At step 404, an adhesive pad is placed on one or more of the plurality of electronic components 104, 106 and 108, such as high power components needing heat dissipation. For an embodiment of the present invention, the adhesive pad is thermally conductive and has the property of adhesion. At step 406, the RF shield 202, with a compressible top surface is formed. The RF shield 202 can be formed in such a way that it encloses the plurality of electronic components 104, 106 and 108 including the adhesive pad 204. At step 408, the RF shield 202 is compressed by application of force 302 on the outside surface. For an embodiment of the present invention, the force 302 is applied vertically, either mechanically or manually. The inside surface of the RF shield 202 comes into physical contact with the adhesive pad 204 on application of the force 302. The plurality of electronic components 104, 106 and 108, including the adhesive pad 204, are enclosed by the RF shield 202. The method is terminated at step 410.

For an embodiment of the present invention, along with RF energy, heat is radiated from the plurality of electronic components 104, 106 and 108. The radiated heat is absorbed by the adhesive pad 204 and transferred to the inside surface of the RF shield 202. The transferred heat is dissipated by the outside surface of the RF shield 202.

The RF shield described above enhances cooling of the electronic components. The RF shield on application of force comes in contact with the adhesive pad which is in physical contact with the plurality of electronic components. This configuration allows the adhesive pad to absorb heat from the plurality of electronic components and transmit the heat to the RF shield, thereby providing an efficient method for cooling the electronic components in conjunction with shielding.

In the foregoing specification, the invention and its benefits and advantages have been described with reference to specific embodiments of an assembly providing both heat dissipation and shielding of electronic components. However, one of ordinary skill in the art would appreciate that various modifications and changes can be made without departing from the scope of the present invention, as set forth in the claims below. Accordingly, the specification and figures are to be regarded in an illustrative rather than a restrictive sense, and all such modifications are intended to be included within the scope of the present invention. The benefits, advantages, solutions to problems, and any element(s) that may cause any benefit, advantage or solution to occur or become more pronounced are not to be construed as critical, required or essential features or elements of any or all the claims. The invention is defined solely by the appended claims, including any amendments made during the pendency of this application, and all equivalents of those claims, as issued.

1. An apparatus for providing radio frequency (RF) shielding of a plurality of electronic components mounted on a printed circuit board, the apparatus comprising:
an adhesive pad, wherein the adhesive pad is in physical contact with the plurality of electronic components, and wherein the adhesive pad is thermally conductive; and
a compressible RF shield enclosing the plurality of electronic components, the compressible RF shield bending on application of a force, the RF shield comprising:
an outside surface, wherein the force bending the compressible RF shield is applied on the outside surface; and
an inside surface, wherein the inside surface makes physical contact with the adhesive pad upon application of the force to the outside surface.

2. The apparatus of claim 1, wherein the compressible RF shield is made of a metal.

3. The apparatus of claim 1, wherein the compressible RF shield prevents radio frequency energy from permeating through the outside surface.

4. The apparatus of claim 1, wherein the outside surface dissipates heat transmitted from the plurality of electronic components.

5. The apparatus of claim 1, wherein the adhesive pad absorbs heat dissipated from the plurality of electronic components.

6. The apparatus of claim 1, wherein the adhesive pad transfers heat to the compressible RF shield through the inside surface.

7. The apparatus of claim 1, wherein the force applied is a vertical force.

8. The apparatus of claim 1, wherein the force is applied manually.

9. The apparatus of claim 1, wherein the force is applied by an individual.

10. An apparatus for providing radio frequency (RF) shielding to a plurality of electronic components in an electronic circuit, the apparatus comprising:
a base board, wherein the plurality of electronic components are mounted on the base board;
an adhesive pad wherein the adhesive pad is in physical contact with at least one of the plurality of electronic components, and wherein the adhesive pad is thermally conductive; and
a compressible RF shield enclosing one or more of the plurality of electronic components, the RF shield bending on application of a force, the compressible RF shield comprising:
a first surface, wherein the force bending the compressible RF shield is applied on the first surface; and
a second surface, wherein the second surface is in physical contact with the adhesive pad.

11. The apparatus of claim 10, wherein the base board is made of an insulating material.

12. The apparatus of claim 10, wherein the base board is a printed circuit board.

13. The apparatus of claim 10, wherein the RF shield is made of a metal.

14. The apparatus of claim 10, wherein the first surface dissipates heat transmitted by the plurality of electronic components.

15. The apparatus of claim 10, wherein the adhesive pad absorbs heat transmitted by the plurality of electronic components.

16. The apparatus of claim 10, wherein the adhesive pad transfers heat to the compressible RF shield through the second surface.

17. The apparatus of claim 10, wherein the adhesive pad is made of thermally conductive material.

18. A method for providing radio frequency (RF) shielding of a plurality of electronic components mounted on a printed circuit board, the method comprising:
placing an adhesive pad on the plurality of electronic components, wherein the adhesive pad is in physical contact with the plurality of electronic components;
forming a compressible RF shield having a top surface, the top surface being compressible; and
compressing the compressible RF shield by application of a force on the top surface, the compressible RF shield making physical contact with the adhesive pad in response to the applied force and enclosing the plurality of electronic components.
